(19) United States
(12) Patent Application Publication
(10) Pub. No.: US 2009/0153481 A1
(43) Pub. Date: Jun. 18, 2009

(54) DATA OUTPUT DEVICE HAVING A PLURALITY OF KEY STICK DEVICES CONFIGURED FOR READING OUT DATA TO A USER AND METHOD THEREOF

(76) Inventors: ADAM M. GUNTHER, Raleigh, NC (US); HUGH E. HOCKETT, Raleigh, NC (US); ERIC KIRCHSTEIN, Raleigh, NC (US)

Correspondence Address: DILLON & YUDELL LLP, 8911 N. CAPITAL OF TEXAS HWY., SUITE 2110, AUSTIN, TX, 78759, US

(21) Appl. No.: 11/954,922

(22) Filed: Dec. 12, 2007

(51) Int. Cl. G09G 5/08; H03K 17/94; G06F 3/033; G09B 21/00

(52) U.S. Cl. 345/161; 341/23; 345/168; 340/407.2

(57) ABSTRACT

A data output device and associated method for reading out data to a computer user. The data output device includes a keyboard having a plurality of key stick devices configured for reading out data. Each key stick device is coupled to a key stick positioning actuator that is responsive to electronic signals corresponding to a unique conventional key. Moreover, the key stick device is actively positioned in one of a plurality of output modes by the key stick positioning actuator. Each one of the plurality of output modes indicates the unique conventional key. The unique conventional key corresponds to a change in a height, or an azimuth, or a tilt angle of the key stick device.

### BACKGROUND OF THE INVENTION

The present disclosure relates to the field of data output devices, and specifically to data output devices for visually-impaired users.

Visually-impaired individuals face many difficulties in receiving text communications from external sources via a computer. Existing remedial methods substitute visual communication, such as text that is displayed on a monitor, with other forms of sensory communication, such as audible and tactile communications. In this regard, tools for audible communication have included screen reading utilities that read out text data. Moreover, tools for tactile communication have included refreshable Braille displays. However, for visually-impaired computer users that cannot read Braille and/or also have auditory impairments, such types of displays and/or screen reading utilities are ineffective.

### BRIEF SUMMARY OF THE INVENTION

A data output device and associated method for reading out data to a computer user are disclosed. The data output device includes a keyboard having a plurality of key stick devices configured for reading out data. Each key stick device is coupled to a key stick positioning actuator that is responsive to electronic signals corresponding to a unique conventional key. Moreover, each key stick device is actively positioned in one of a plurality of output modes by the key stick positioning actuator. Each one of the plurality of output modes indicates the unique conventional key. The unique conventional key corresponds to a change in a height, or an azimuth, or a tilt angle of the key stick device.

### BRIEF DESCRIPTION OF THE SEVERAL VIEWS OF THE DRAWINGS

Aspects of the invention itself will best be understood by reference to the following detailed description of an illustrative embodiment when read in conjunction with the accompanying drawings, where:

FIG. 1 depicts an exemplary computer in which the present invention may be implemented;

FIG. 2 depicts a perspective view of an exemplary data output device in which the present invention may be implemented;

FIG. 3 is a top view of the exemplary data output device shown in FIG. 2 in which the present invention may be implemented;

FIG. 4 depicts a partial view of an arrangement of conventional keys in an exemplary QWERTY keyboard that is useful for understanding the invention;

FIG. 5 is a perspective view of an exemplary key stick device depicting various output modes, according to an embodiment of the present invention;

FIG. 6 is a perspective view of the exemplary key stick device of FIG. 5 at various output modes correlating to various detent positions that is useful for understanding the invention;

FIG. 7 illustrates an exemplary position grid depicting detent positions relative to an exemplary key stick device and how a combination of detent positions correlate to a unique conventional key; and

FIG. 8 is a high-level flow-chart of exemplary method steps taken for reading out data from a keyboard.

### DETAILED DESCRIPTION OF THE INVENTION

As will be appreciated by one skilled in the art, the present invention may be embodied as a method, apparatus (system), or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module”, “device”, or “system.” Furthermore, the present invention may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present invention may be written in an object oriented programming language such as Java® (JAVA is a trademark or registered trademark of Sun Microsystems, Inc. in the United States and other countries), Smalltalk® (SMALLTALK is a trademark or registered trademark of Cincom Systems, Inc.), C++ or the like. However, the computer program code for carrying out operations of the present invention may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the Internet using an Internet Service Provider).

The present invention is described below with reference to flowchart illustrations and/or block diagrams of methods, apparatuses (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

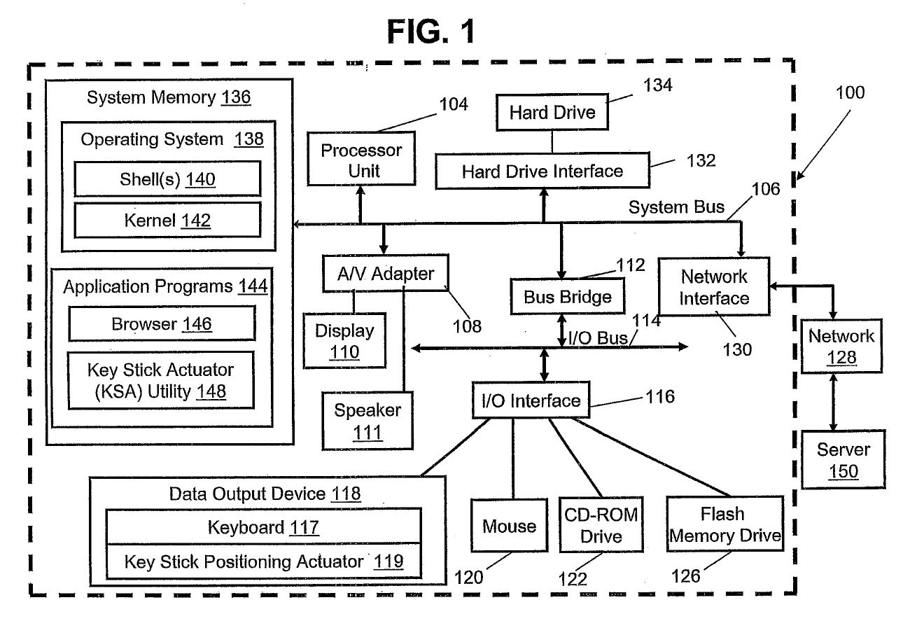

With reference now to the figures, and in particular to FIG. 1, there is depicted a block diagram of an exemplary computer 100, with which the present invention may be utilized. Computer 100 includes a processor unit 104 that is coupled to a system bus 106. An audio/video (A/V) adapter 108, which drives/supports a display 110 and a speaker 111, is also coupled to system bus 106. System bus 106 is coupled via a bus bridge 112 to an Input/Output (I/O) bus 114. An I/O interface 116 is coupled to I/O bus 114. I/O interface 116 affords communication with various I/O devices, including a data output device 118 (which includes a keyboard 117 and key stick positioning actuators 119), a mouse 120, a Compact Disk-Read Only Memory (CD-ROM) drive 122, and a flash memory drive 126. The format of the ports connected to I/O interface 116 may be any known to those skilled in the art of computer architecture, including but not limited to Universal Serial Bus (USB) ports.

Computer 100 is able to communicate with a server 150 via a network 128 using a network interface 130, which is coupled to system bus 106. Network 128 may be an external network such as the Internet, or an internal network such as an Ethernet or a Virtual Private Network (VPN). Server 150 may be architecturally configured in the manner depicted for computer 100.

A hard drive interface 132 is also coupled to system bus 106. Hard drive interface 132 interfaces with a hard drive 134. In one embodiment, hard drive 134 populates a system memory 136, which is also coupled to system bus 106. System memory 136 is defined as a lowest level of volatile memory in computer 100. This volatile memory may include additional higher levels of volatile memory (not shown), including, but not limited to, cache memory, registers, and buffers. Code that populates system memory 136 includes an operating system (OS) 138 and application programs 144.

OS 138 includes a shell 140, for providing transparent user access to resources such as application programs 144. Generally, shell 140 (as it is called in UNIX® (UNIX is a registered trademark of The Open Group in the United States and other countries)) is a program that provides an interpreter and an interface between the user and the operating system. Shell 140 provides a system prompt, interprets commands entered by mouse 120, or other user input media, and sends the interpreted command(s) to the appropriate lower levels of the operating system (e.g., kernel 142) for processing. As depicted, OS 138 also includes kernel 142, which includes lower levels of functionality for OS 138. Kernel 142 provides essential services required by other parts of OS 138 and application programs 144. The services provided by kernel 142 include memory management, process and task management, disk management, and I/O device management.

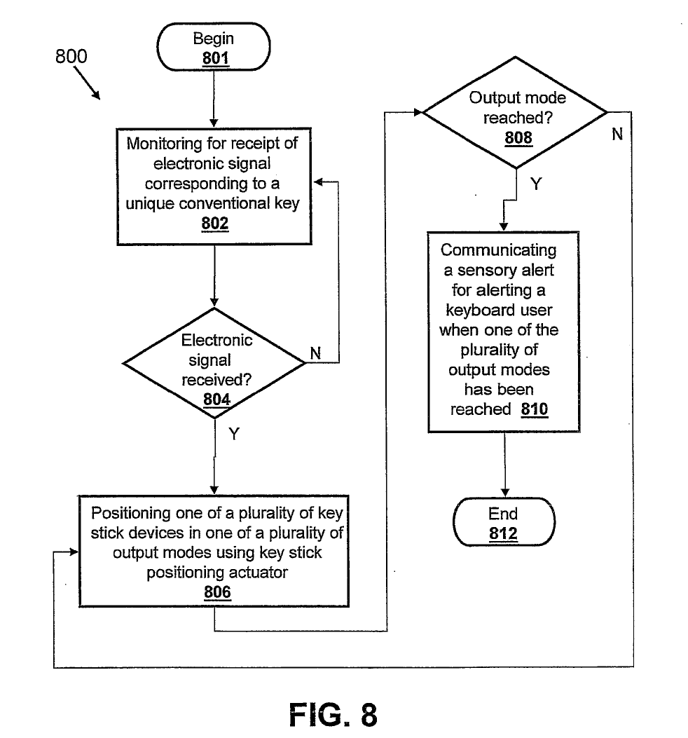

Application programs 144 include a browser 146. Browser 146 includes program modules and instructions enabling a World Wide Web (WWW) client (i.e., computer 100) to send and receive network messages to the Internet. Computer 100 may utilize HyperText Transfer Protocol (HTTP) messaging to enable communication with server 150. Application programs 144 in system memory 136 also include a Key Stick Actuator (KSA) Utility 148. KSA utility 148 performs the functions illustrated below in FIG. 8. KSA utility 148 communicates with OS 138, which in turn communicates with I/O Interface 116 by way of system bus 106, bus bridge 112, and I/O Bus 114. I/O Interface communicates with Data Output Device 118. KSA utility 148 processes electronic signals from a multitude of sources, such as server 150 in network 128, as well as from other application programs 144.

The hardware elements depicted in computer 100 are not intended to be exhaustive, but rather represent and/or highlight certain components that may be utilized to practice the present invention. For instance, computer 100 may include alternate memory storage devices such as magnetic cassettes, Digital Versatile Disks (DVDs), Bernoulli cartridges, and the like. These and other variations are intended to be within the spirit and scope of the present invention.

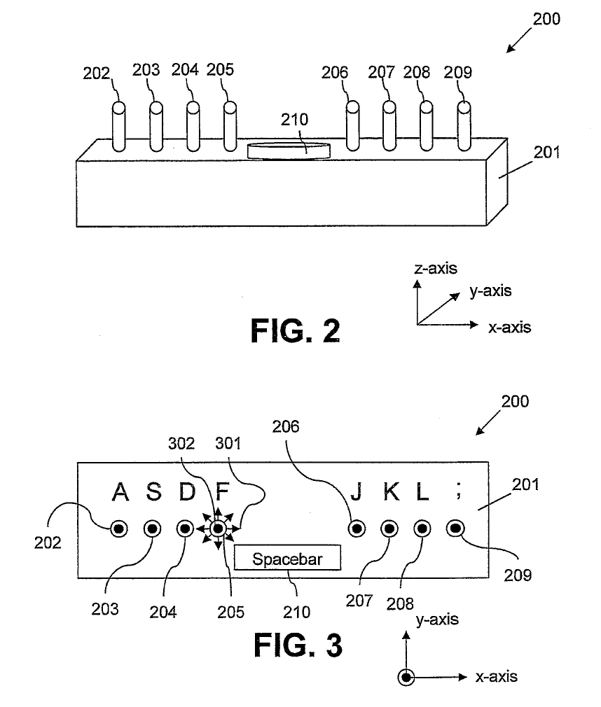

Referring now to FIG. 2, a graphical representation of an exemplary data output device 200 is shown. Data output device 200 includes a keyboard 117 having a plurality of key stick devices 202-209 and a spacebar key 210. In addition, data output device 200 includes a plurality of key stick positioning actuator 119 (FIG. 1). Each key stick positioning actuator 119 is coupled to a respective key stick device 202-209 and to spacebar key 210. Each key stick positioning actuator is responsive to electronic signals corresponding to a unique conventional key and actively positions its respective key stick device 202-209 from a first position to a second position according to one of a plurality of output modes. The term “unique conventional key” refers to a key that is typically utilized in a conventional keyboard. Such keys include, but are not limited to: a typewriter key, a WINDOWS® (a registered trademark of Microsoft Corp.) key, an application key, a function key, a numeric keypad key, a cursor control key, an enter key, a command key, and spacebar key 210. Moreover, such conventional keys are typically arranged in a conventional layout, such as in the case of a QWERTY layout or a DVORAK layout.

Referring now to FIG. 3, a top view of exemplary data output device 200 is shown. According to this embodiment of the invention, key stick devices 202-209 are arranged in a home row that is similarly arranged as would be typically represented by home row keys ‘A’, ‘S’, ‘D’, ‘F’, ‘J’, ‘K’, ‘L’, ‘;’ that are arranged in a QWERTY layout. Each key stick device 202-209, can be positioned (i.e., tilted and/or depressed) from an initial position (i.e. upright along a z-axis). For illustrative purposes only, key stick device 205 is shown having directional arrows 301 and dot 302. Directional arrows 301 indicate the various azimuths in which key stick device 205 can be urged (or positioned). Dot 302 indicates that key stick device 205 can be pulled-down by key stick positioning actuator 119 (FIG. 1), thus producing a change in a positional height of key stick device 205. Pulling-down on key stick device 205 communicates to a keyboard user by tactile feel the conventional alphanumeric key ‘F’. By tactile feel, an assumption is made that each one of the user's fingers are respectively touching/resting on key stick device while the key stick device is changing position. It should be recognized that while the above example focuses on the possible actuated movements of key stick device 205, any one of key stick devices 202-204 and 206-209 can be positioned as illustrated by key stick device 205.

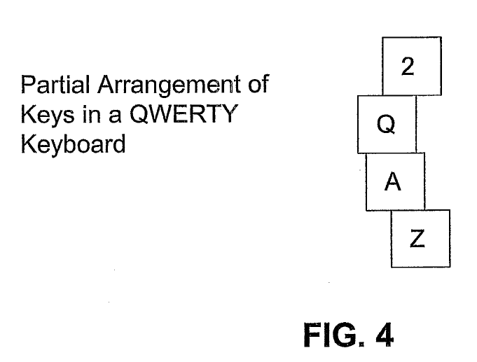

To better illustrate the functionality of key stick devices 202-209, a partial arrangement of conventional keys associated with a QWERTY layout is shown in FIG. 4. In this partial view of a QWERTY layout, conventional keys ‘Z’, ‘A’, ‘Q’, and ‘2’ are shown as they are typically arranged. In a QWERTY layout, the ‘A’ key forms part of what is commonly known as a home row (i.e., keys A, S, D, F, G, H, J, K, L) of keys. Below and to the right of the ‘A’ key is the ‘Z’ key. Above the ‘A’ key is the ‘Q’ key, which is in turn below and to the right of the ‘2’ key. Thus, conventional keys ‘Z’, ‘A’, ‘Q’, and ‘2’ each form part of distinct rows of keys. While it is recognized that the QWERTY layout and its international variants is currently the most common type of keyboard key layout that is implemented, the invention is not limited in this regard, and other conventional keyboard key layouts that are familiar to a keyboard user can also be used in combination with the invention.

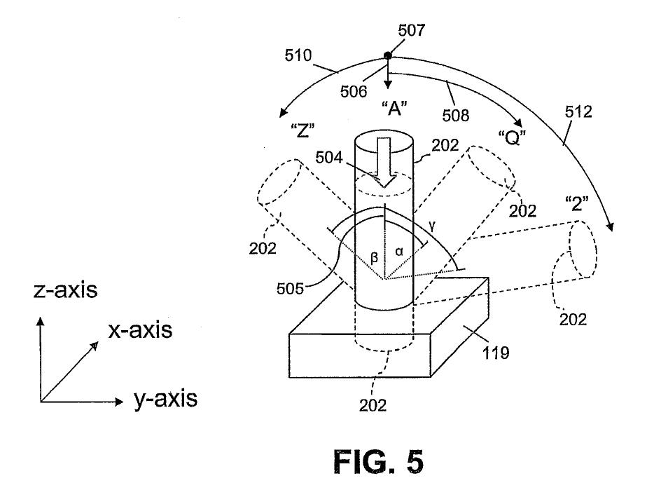

Referring now to FIG. 5, key stick device 202 (FIG. 2) is shown. Key stick device 202 is coupled to key stick positioning actuator 119. When key stick positioning actuator 119 receives an electronic signal representing data for outputting the letter ‘A’, key stick positioning actuator 119 will pull-down along a z-axis (as shown by arrows 504 and 506). As a result of this pull-down motion, the positional height of key stick device 205 relative to an initial position is changed. When key stick positioning actuator 119 receives an electronic signal representing data for outputting the letter ‘Q’, key stick positioning actuator 119 will tilt key stick device 202 towards a north azimuth along a y-axis. In addition to tilting towards a north azimuth, key stick device 202 will also tilt (i.e., movement along directional path 508) at an angle (or tilt angle) α of 45 degrees. Generally, the tilt angle is measured with respect to a longitudinal axis 505. The combination of changing one or more of the aforementioned variables (i.e., positional height, azimuth, and tilt angle), which collectively form an output mode, indicates a unique conventional key (e.g., the letter ‘Q’).

Similarly, when the ‘Z’ key is to be represented by an output mode, key stick positioning actuator 119 tilts (i.e., movement along directional path 510) key stick device 202 towards a south azimuth and at a tilt angle β of 45 degrees from longitudinal axis 505. Moreover, when the ‘2’ key is to be represented by an output mode, key stick positioning actuator 119 tilts key stick device 202 towards a north azimuth, but at a tilt angle that is greater than the 45 degrees that is required to represent the ‘Q’ key. In this regard, key stick device 202 is tilted (i.e., movement along directional path 512) at a tilt angle γ of about 80 degrees from longitudinal axis 505. Generally, the movement of key stick device 202 from a first position to a second position is in a direction of a relative position of a desired conventional key on a conventional keyboard. Thus, with a single key stick device 202, a plurality of unique conventional keys can be represented. Key stick positioning actuator 119 can be implemented in various ways, including, but not limited to the use of: an electromechanical solenoid, a piezoelectric actuator, a stepper motor, a servomechanism, and the like.

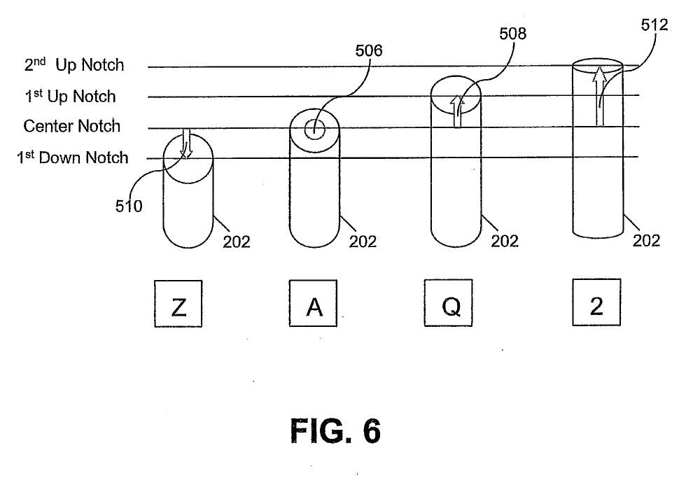

To facilitate a computer user's identification of one of the various possible output modes associated with a particular key stick device 202-209, a detent mechanism (not shown) for resisting movement can be utilized. According to one embodiment, the detent mechanism for resisting movement includes a spring-loaded ball bearing that locates in small incremental depressions/notches. With reference now to FIG. 6, key stick device 202 (FIG. 2) is shown in four distinct output modes. Each one of the four distinct output modes indicates a unique conventional key, ‘Z’, ‘A’, ‘Q’, or ‘2’. Moreover, each distinct output mode shown in FIG. 6 is attained by tracing the movement of key stick device 202 to locate the depression/notch (not shown) which, when located, identifies when a particular output mode has been reached. Key stick device 202 reaches output modes representing unique conventional keys ‘Z’, ‘A’, ‘Q’, or ‘2’ by moving from an initial position through directional paths 510, 506, 508, and 512 of FIG. 5, respectively. For instance, if key stick device 202 is to start from an initial position (e.g., as shown by upright and non-depressed key stick device 202 in FIG. 5), key stick device 202 must first unlock from a center notch and move along directional path 512. Along directional path 512, key stick device reaches and unlocks from a 1^{st} Up Notch until a 2^{nd} Up Notch is reached.

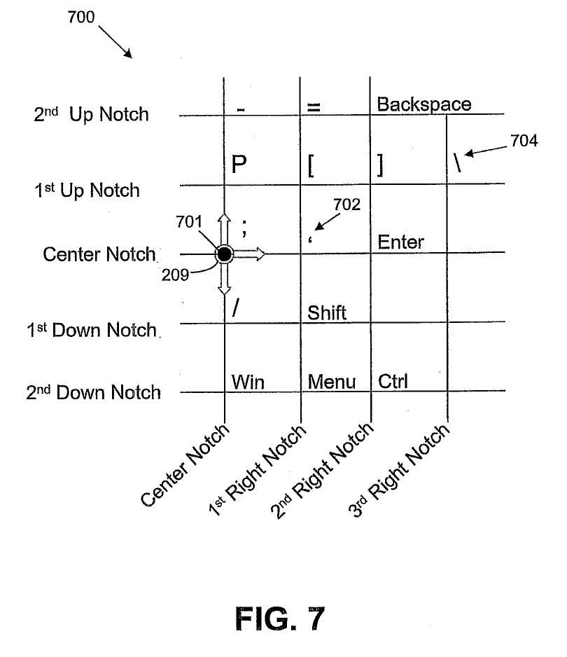

It is important to note that there can be any number of output modes that can be associated with a single key stick device 202-209. The exemplary embodiments illustrated thus far have shown how the key stick device can be tilted in a direction of a North/South azimuth to attain output modes corresponding to unique conventional keys. However, key stick device 202-209 can also be tilted in a direction of an East/West azimuth, or in any combination of North/South/East/West azimuths. Referring now to FIG. 7, an exemplary position grid 700 depicting detent positions relative to exemplary key stick device 209 is shown. According to exemplary position grid 700, key stick device 209 can be positioned such that up to sixteen output modes corresponding respectively to sixteen unique conventional keys can be reached. For example, when key stick device 209 is tilted from an initial position 701 along an East azimuth until reaching a 1^{st} Right Notch, an output mode corresponding to a unique conventional key (i.e., quotation key 702) is reached. Moreover, in order for an output mode corresponding to a conventional backslash “\” key 704 to be reached, key stick device 209 can move along any number of directional paths from an initial position: (i) moving in a direction of an East azimuth until reaching a 3^{rd} Right Notch position, and from the 3^{rd} Right Notch position moving in a direction of a North azimuth until reaching a 1^{st} Up Notch position; or (ii) moving in a direction of the North azimuth until reaching the 1^{st} Up Notch position, and from the 1^{st} Up Notch position moving in a direction of an East azimuth until reaching the 3^{rd} Right Notch position.

As described in exemplary manner below, the invention also provides for a method for reading out data from a keyboard. With reference now to FIG. 8, a high-level flow-chart 800 of the method is shown. After initiator block 801, KSA utility 148 (FIG. 1) monitors for receipt of an electronic signal corresponding to a unique conventional key, as depicted in block 802. From block 802, method 800 proceeds to decision block 804, where a determination is made whether the electronic signal corresponding to a unique conventional key is received. If the electronic signal is not received, method 800 returns to block 802 until the electronic signal is received by KSA utility 148. However, if the electronic signal is received, method 800 proceeds to block 806, where one of a plurality of key stick devices 202-209 (FIG. 2) from a keyboard 117 (FIGS. 1 and 2) is positioned.

The plurality of key stick devices 202-209 are positioned in one of a plurality of output modes using a key stick positioning actuator 119 (FIGS. 1 and 5) coupled to one of the plurality of key stick devices 202-209. Each one of the plurality of output modes indicates a unique conventional key that corresponds to a change in a height, an azimuth, and/or a tilt angle of one of the plurality of key stick devices 202-209. From block 806, method 800 proceeds to decision block 808, where a determination is made whether an output mode has been detected. If an output mode has not been detected, method 800 returns to block 806. However, if an output mode has been detected, a sensory alert is communicated to a keyboard user. The sensory alert alerts a keyboard user when one of the plurality of output modes has been reached.

The sensory alert may take several possible forms. In one embodiment, the sensory alert is a tactile sensory alert. The tactile sensory alert includes a detent mechanism coupled to one of the plurality of key stick devices 202-209. According to another embodiment, the tactile sensory alert includes a vibrating mechanism coupled to one of the plurality of key stick devices 202-209. In both types of tactile sensory alerts, the alerts tactilely indicate to the keyboard user which one of the plurality of output modes has been reached. In addition, the sensory alert can support an audible sensory alert. The method 800 ends at terminator block 812.

Note that the flowchart and block diagrams in the figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to preferred embodiments thereof, it will be apparent that modifications and variations are possible without departing from the scope of the invention defined in the appended claims.

What is claimed is:

1. A data output device comprising:
a keyboard having a plurality of key stick devices configured for reading out data;
a key stick positioning actuator coupled to each one of said plurality of key stick devices;
wherein said key stick positioning actuator is responsive to electronic signals corresponding to a unique conventional key;
wherein one of said plurality of said key stick devices is actively positioned in one of a plurality of output modes by said key stick positioning actuator; and
wherein each one of said plurality of output modes indicates said unique conventional key, said unique conventional key corresponding to a change in a height, or an azimuth, or a tilt angle of one of said plurality of key stick devices.

2. The data output device of claim 1, further comprising a detent mechanism coupled to each one of said plurality of key stick devices to tactilely indicate to a user one of said plurality of output modes.

3. The data output device of claim 1, wherein each one of said plurality of output modes is produced by a movement of one of said plurality of key stick devices from a first position to a second position, and wherein said movement is in a direction of a relative position of a desired key on a conventional keyboard.

4. The data output device of claim 1, wherein the unique conventional key includes a typewriter key, or a WINDOWS key, or an application key, or a function key, or a numeric keypad key, or a cursor control key, or an enter key, or a command key, or a spacebar key.

5. A method for reading out data from a keyboard, the method comprising:
monitoring for receipt of an electronic signal corresponding to a unique conventional key; and
responsive to receiving said electronic signal, positioning one of a plurality of key stick devices configured for reading out data from a keyboard in one of a plurality of output modes using a key stick positioning actuator coupled to one of the plurality key stick devices;
wherein each one of said plurality of output modes indicates said unique conventional key, said unique conventional key corresponding to a change in a height, or an azimuth, or a tilt angle of said one of said plurality of key stick devices.

6. The method of claim 5, the method further comprising:
communicating a sensory alert for alerting a keyboard user when one of said plurality of output modes has been reached.

7. The method of claim 6, wherein the sensory alert is a tactile sensory alert.

8. The method of claim 7, wherein the tactile sensory alert is a detent mechanism coupled to one of said plurality of key stick devices to tactilely indicate to a user one of said plurality of output modes.

9. The method of claim 7, wherein the tactile sensory alert is a vibrating mechanism coupled to one of said plurality of key stick devices to tactilely indicate to a user one of said plurality of output modes.

10. The method of claim 6, wherein the sensory alert is an audible sensory alert.
